(19) United States
(12) Patent Application Publication
(10) Pub. No.: US 2006/0038291 A1
(43) Pub. Date: Feb. 23, 2006

(54) Electrode structure of a semiconductor device and method of manufacturing the same

(76) Inventors: Hyun-soo Chung, Hwaseong-si (KR); Sung-min Sim, Seongnam-si (KR); Myeong-soon Park, Suwon-si (KR); Dong-hyeon Jang, Suwon-si (KR); Young-hee Song, Seongnam-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/080,956

(22) Filed: Mar. 16, 2005

(30) Foreign Application Priority Data
Aug. 17, 2004 (KR) 10-2004-0064586

(51) Int. Cl. H01L 23/48; H01L 21/44

(52) U.S. Cl. 257/738; 438/613; 438/708; 257/780; 29/843

(57) ABSTRACT

In the manufacture of a semiconductor device, a photosensitive layer is deposited to cover an exposed portion of an electrode with the photosensitive layer. The photosensitive layer is then subjected to a photolithography process to partially remove the photosensitive layer covering the electrode. The electrode may be a ball electrode or a bump electrode, and the semiconductor device may be contained in a wafer level package (WLP) or flip-chip package.

### BACKGROUND OF THE INVENTION

1. Field of the Invention

The present invention generally relates to integrated circuit (IC) chips and packages, and more particularly, the present invention relates to the electrode structures of IC chips and devices, and to methods of forming electrode structures for IC chips and packages.

2. Description of the Related Art

As integrated circuits (IC's) advance toward higher speeds and larger pin counts, first-level interconnection techniques employing wire bonding technologies have approached or even reached their physical limits. New improved technologies for achieving fine-pitch wire bonding structures cannot keep pace with the demand resulting from increased IC chip processing speeds and higher IC chip pin counts. Accordingly, the current trend is to replace wire bonding structures with other package structures, such as a flip chip packages and wafer level packages (WLP).

Flip chip packages and WLP structures are partially characterized by the provision of bump electrodes or ball electrodes (typically made of solder) which connect to the interconnection terminals located at the principle surface of one or more IC chips contained in the packages. Device reliability is largely dependent on the structure and material of each electrode bump/ball and its effectiveness as an electrical interconnect.

A conventional solder bump structure will be described with reference to FIGS. 1 and 2, where like elements are designated by the same reference numbers. FIG. 1 is a schematic cross-sectional view of a flip chip package, and FIG. 2 is a schematic cross-sectional view of a solder bump structure mounted within the flip chip package of FIG. 1.

Referring collectively to FIGS. 1 and 2, an IC chip 1 is equipped with a chip pad 2, which is typically formed of aluminum. An opening is defined in one or more passivation layers 3 and 4 which expose a surface of the chip pad 2. A solder bump 5 is made to electrically contact the chip pad 2 through the opening in the layers 3 and 4.

Typically, one or more under bump metallurgy (UBM) layers 7 are interposed between the solder bump 5 and the chip pad 2. The UBM layers 7 function to reliably secure the bump 5 to the chip pad 2, and to prevent moisture absorption into chip pad 2 and IC chip 1. For example, the UBM layers 7 may include an adhesion layer deposited by sputtering of Cr, Ti, or TiW, and a wetting layer deposited by sputtering of Cu, Ni, NiV. An oxidation layer of Au may also be deposited.

The solder bump 5 is mounted at its other end to a printed circuit board (PCB) pad 8 of a PCB substrate 9, and the PCB pad 8 is electrically connected to a solder ball 10 on the opposite side of the PCB substrate 9. Reference number 12 of FIG. 1 denotes a heat sink member for dissipating heat generated by the IC chip 1, and reference number 11 of FIG. 1 denotes a stiffening member for adding physical support to the overall package.

Mechanical stresses on the solder bump are a source of structural defects which can substantially impair device reliability. FIG. 2 illustrates an example in which stresses have caused cracks or fissures 12 to be formed in the solder bump 5. The larger the cracks, the more the interconnection becomes impaired, and device failures can readily occur when cracks propagate completely through the solder bump structure.

U.S. Pat. No. 6,187,615 (issued Feb. 13, 2001, in the name of Nam Seog Kim et al.) discloses a semiconductor package which is intended to strengthen the structural characteristics of the solder bump connections contained therein. As shown in FIG. 3, the structure 40 includes a patterned conductor 17 extending over a first passivation layer 14 and connected at one end to a chip pad 12. An insulating layer 24 has an opening which exposes another end of the patterned conductor 17. A bump electrode 32 is formed on the insulating layer 24 and the patterned conductor 17, and a barrier metal 27 is interposed there between. Further, a reinforcing layer 34 is formed on the insulating layer 24 to support the solder bump 32. The reinforcing layer 34 is formed by dispensing and then curing a low viscosity liquid polymer. The low viscosity of the liquid polymer allows surface tensions to draw the polymer up the side of solder bump 32 to create a concave support for the solder bump 32. The concave support absorbs stresses applied to the solder bump 32 when the package is mounted on a circuit board.

In practice, however, curing characteristics of the low viscosity liquid polymer are difficult to precisely control. As a result, it is difficult to maintain uniformity of the exposed portions of the bump electrodes across the surface of the chip. This lack of uniformity can result in poor adhesion and/or poor electrical interconnection when the chip is later mounted to the PCB substrate.

### SUMMARY OF THE INVENTION

According to a first aspect of the present invention, a method of manufacturing a semiconductor device is provided which includes depositing a photosensitive layer to cover an exposed portion of an electrode with the photosensitive layer, and subjecting the photosensitive layer to a photolithography process to partially remove the photosensitive layer covering the electrode.

According to another aspect of the present invention, a method of manufacturing a semiconductor device is provide which includes providing a semiconductor element which includes a surface and a plurality of electrodes having respective bottom portions mounted to the surface, depositing a photosensitive layer to cover the surface and the electrodes of the semiconductor element, and subjecting the photosensitive layer to a photolithography process to partially remove the photosensitive layer so as to expose respective top portions of the electrodes.

According to still another aspect of the present invention, a method of manufacturing a wafer level package is provided which includes providing a wafer having a surface which includes a plurality of chip regions separated by scribe lines, and a plurality of electrodes having respective bottom surfaces mounted in each of the chip regions, covering the surface of the wafer with a photosensitive layer, and subjecting the photosensitive layer to a photolithography process to partially remove the photosensitive layer so as to expose respective top portions of the electrodes in each of the chip regions.

According to yet another aspect of the present invention, a semiconductor device is provided which includes an electrode which includes a bottom portion mounted to a conductive layer and which is partially embedded in a polymer layer, where a top portion of the electrode is exposed through an opening in the polymer layer, and where the polymer layer is formed of a material that is photosensitive when in a pre-cured state.

According to another aspect of the present invention, a semiconductor device is provided which includes a semiconductor element which includes a surface and a plurality of electrodes having respective bottom portions mounted to the surface, and a polymer layer which covers the surface of the semiconductor element and which includes a plurality of openings which respectively partially expose a top portion of the electrodes, where the polymer layer is formed of a material that is photosensitive when in a pre-cured state.

According to still another aspect of the present invention, a semiconductor device is provided which includes a semiconductor element which includes a conductive layer and a plurality of electrodes having respective bottom portions mounted to the conductive layer, and a polymer layer which contacts the conductive layer of the semiconductor element and which includes a plurality of openings which respectively partially expose a top portion of the electrodes, where a diameter of each of the electrodes is greater than a diameter of each of the exposed top portions of the electrodes.

### BRIEF DESCRIPTION OF THE DRAWINGS

The above and other aspects and features of the present invention will become readily understood from the detailed description that follows, with reference to the accompanying drawings, in which:

FIG. 1 is a schematic cross-sectional view of a flip chip package;

FIG. 2 is a schematic cross-sectional view of a solder bump mounted within the flip chip package of FIG. 1;

FIG. 3 is a schematic cross-sectional view of a semiconductor package which includes a reinforcing layer in support of a solder bump;

FIGS. 4A through 4G are schematic cross-sectional views for explaining a method of manufacturing a semiconductor package according to an embodiment of the present invention;

FIGS. 5A through 5H are schematic cross-sectional views for explaining a method of manufacturing a semiconductor package according to another embodiment of the present invention;

FIG. 6 is a schematic cross-sectional view of a flip chip package according to an embodiment of the present invention; and

FIG. 7 is a schematic cross-sectional view of a solder bump structure contained in the flip chip package of FIG. 6 according to an embodiment of the present invention.

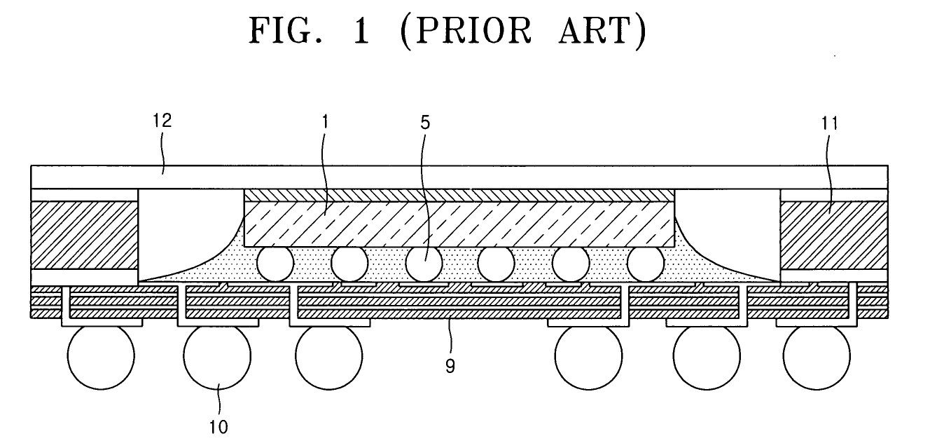

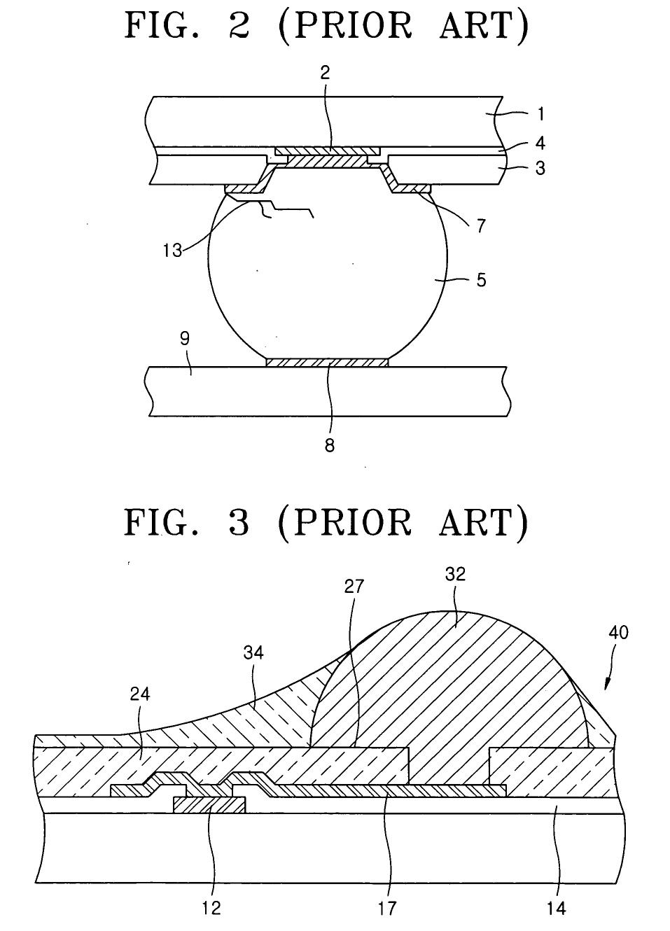

### DETAILED DESCRIPTION OF PREFERRED EMBODIMENTS

The present invention will now be described in detail with reference to preferred, but non-limiting, embodiments of the invention.

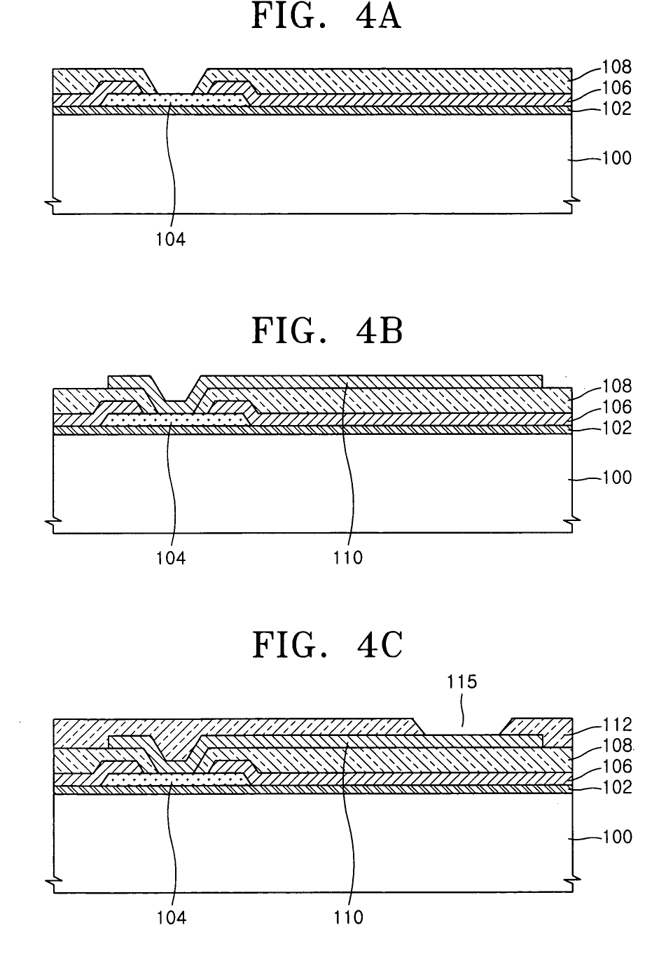

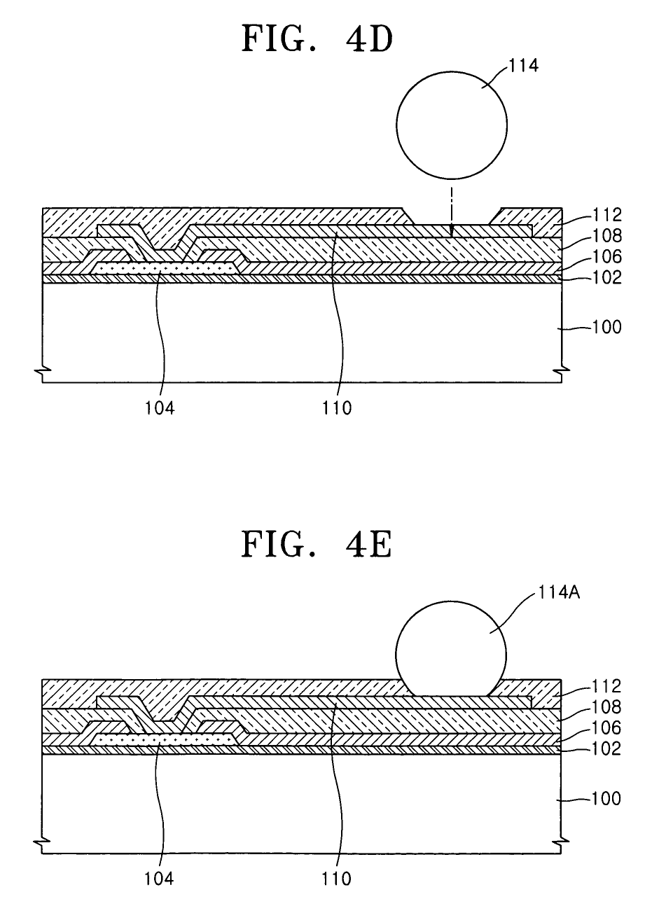

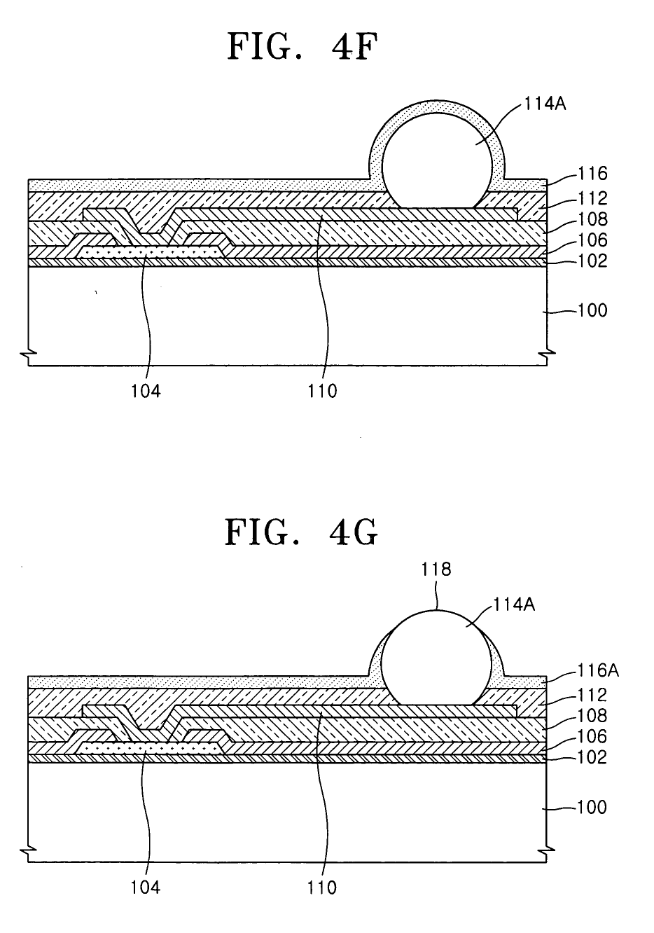

FIGS. 4A through 4G are schematic cross-sectional views for explaining a method of manufacturing a semiconductor package according to an embodiment of the present invention.

Referring initially to FIG. 4A, a semiconductor structure is fabricated or provided so as to generally include a semiconductor substrate 100, an integrated circuit layer 102, a chip pad 104, a passivation layer 106, and an insulating layer 108. The insulating layer may, for example, be formed of BCB (Benzo Cyclo Butene), polyimide, epoxy, silicon oxide, silicon nitrite, or composites of these materials. Also, as shown, an opening is formed through the passivation layer 106 and the insulating layer 108 to expose a top surface region of the chip pad 104. In this example, the insulating layer 108 extends to the surface of the chip pad 104, and accordingly, the sidewalls of the opening are defined by the insulating layer 108.

Referring to FIG. 4B, a conductive redistribution pattern 110 is formed on the insulating layer 108 so as to electrically contact the chip pad 104 via the opening in the insulating layer 108 and the passivation layer 106.

Then, referring to FIG. 4C, an insulating layer 112 is deposited with an opening therein that exposes a top surface portion of the redistribution pattern 110. In this embodiment, the exposed surface portion of the redistribution pattern 110 defines a solder ball pad 115.

Next, referring to FIGS. 4D and 4E, a solder ball 114 is positioned on the solder ball pad 115, and then subjected to a thermal reflow process to adhere the resultant reflowed solder ball 114A to the underlying solder ball pad 115.

Then, referring to FIG. 4F, a photosensitive polymer layer 116 is coated over the structure of FIG. 4E so as to cover the reflowed solder ball 114A and the insulating layer 112. The photosensitive polymer layer 116 may, for example, be formed of polyimide or PBO (PolyBenzOxazol), and may, for example, be deposited by screen printing, spin coating, or dispensing techniques, or by dipping the structure of FIG. 4E into a liquid of the polymer material.

Next, referring to FIG. 4G, the photosensitive polymer layer 116 of FIG. 4F is subjected to a photolithography process in which a portion of the polymer layer is removed to define a reinforcing polymer layer 116A having an opening which exposes a top portion of the solder ball 114A. As illustrated, a portion of the reinforcing polymer layer 11 6A surrounds a sidewall portion of the solder ball 114A. Preferably, the diameter of the solder ball 114A is greater than a diameter in the opening in the reinforcing polymer layer 116A. In other words, the diameter of the solder ball 114A is greater than the diameter of the exposed portion of the solder ball 114A.

The photolithography process includes well-known exposure and development processes to remove selected portions of the photosensitive polymer layer 116. In addition, after development, the process preferably includes heat treatment at a temperature which exceeds the viscosity temperature of the polymer material of the layer 116. Such heat treatment is effective in achieving curing and reflowing of the photosensitive polymer layer 116. As illustrated in FIG. 4G, the reflow of the polymer material results in the tapering of the portion of the reinforcing polymer layer 116A contacting the side of the solder ball 114A. For example, in the case of polyimide, the heat treatment may be conducted at 300° C. to 350° C. Also for example, in the case of PBO, the heat treatment may be conducted at 280° C. to 350° C.

Although not shown, the IC chip structure of FIG. 4G typically will include a plurality of solder balls 114A. Also, while the invention is not limited to wafer level processing, the IC chip structure of FIG. 4G may constitute one of a plurality of simultaneously formed chip structures on a single semiconductor wafer. In this case, scribe lines between adjacent pairs of IC chips on the wafer are preferably exposed during the same photolithography process used to expose the solder ball 114A through the reinforcing layer 116A. The wafer may then be subjected to a sawing process in which it is separated into a plurality of IC chips along the scribe lines. Removal of the photoresistive polymer layer over the scribe lines is effective in avoiding the dicing saw from becoming contaminated with polymer residues.

The reinforcing polymer layer 116A of FIG. 4G is effective in absorbing various stresses applied to solder ball, particularly when the IC chip is mounted to a circuit board and used for an extended period of time. Additionally, in contrast to the fabrication technique described previously in connection with FIG. 3, the use of a photoresistive polymer layer and photolithography to expose the solder ball 114A through the reinforcing layer 116A allows for more precise structural definition of the exposed portion of the solder ball 114A. As such, better uniformity of the exposed portions across the plural solder balls of each IC chip can be realized, which in turn allows for improved adhesion and electrical contact with the printed circuit board of any later formed IC package.

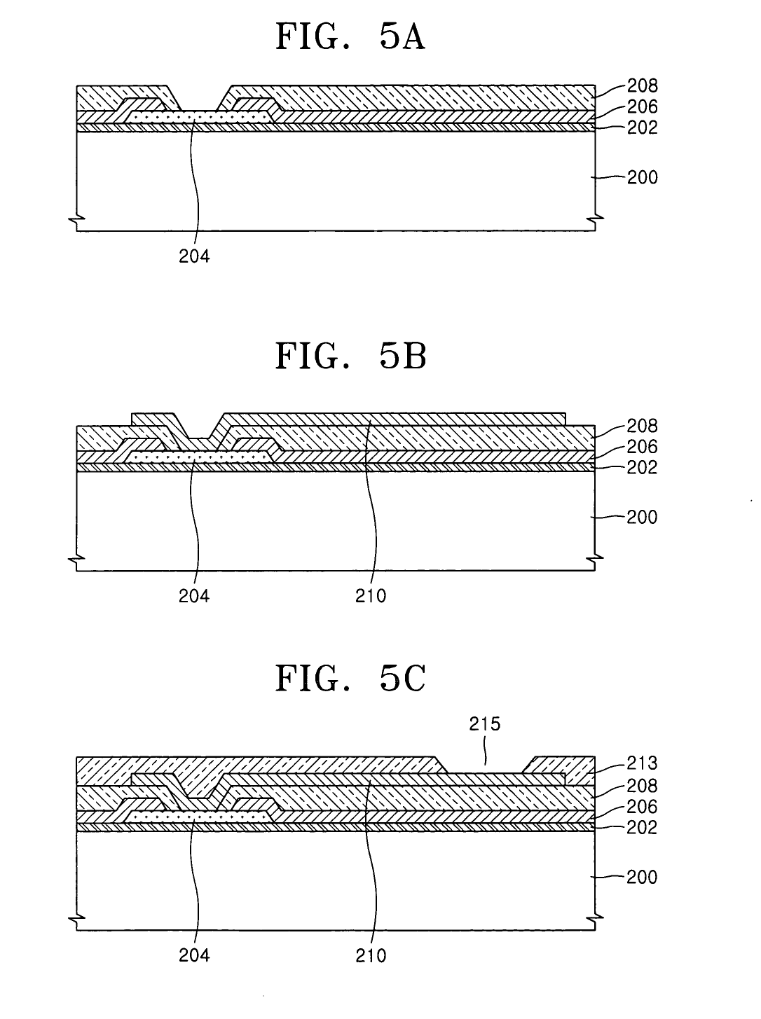

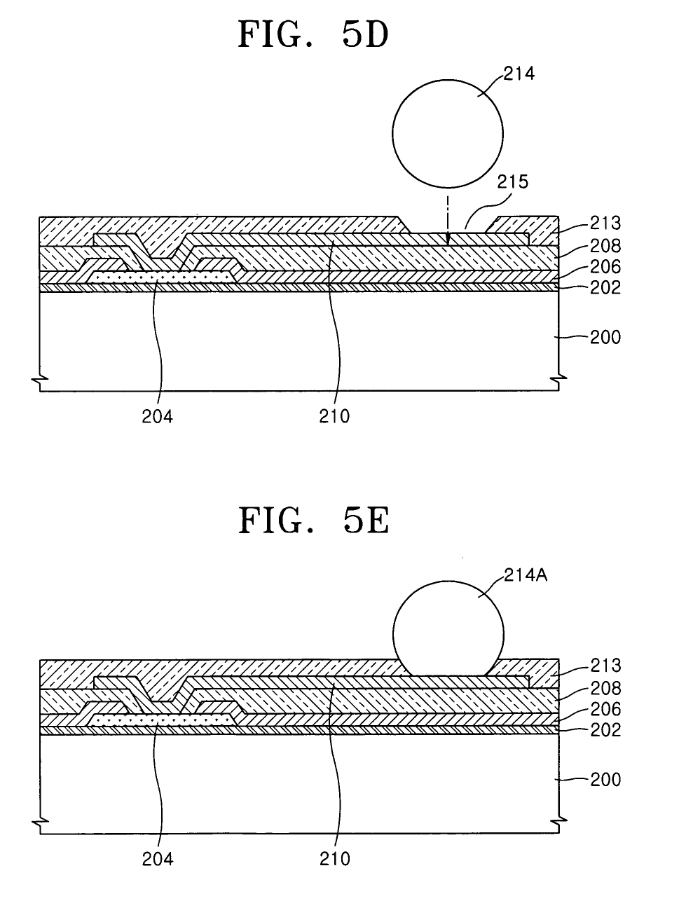

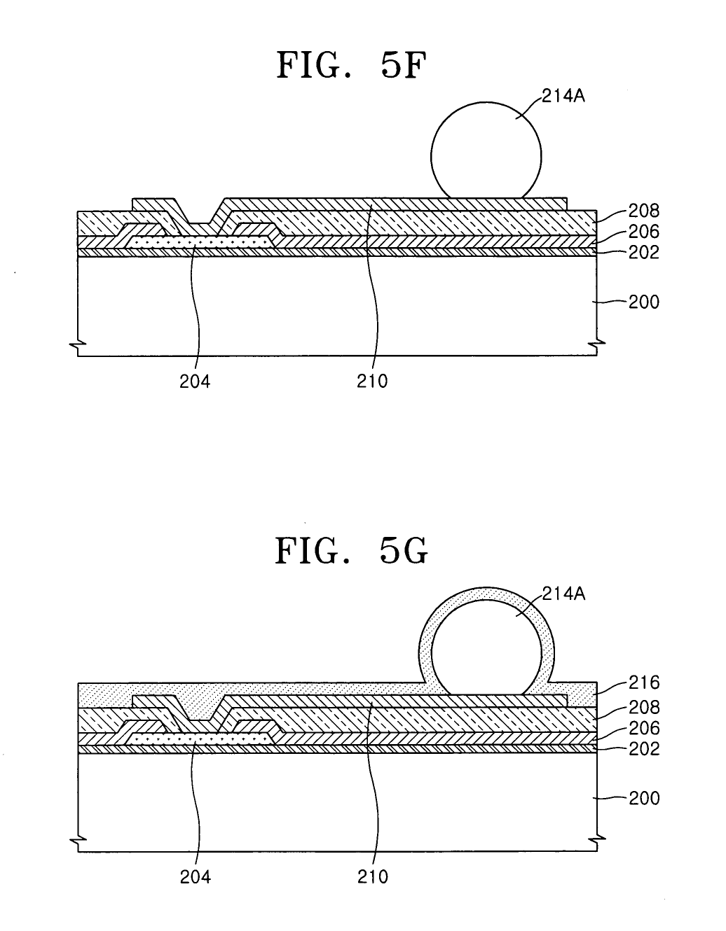

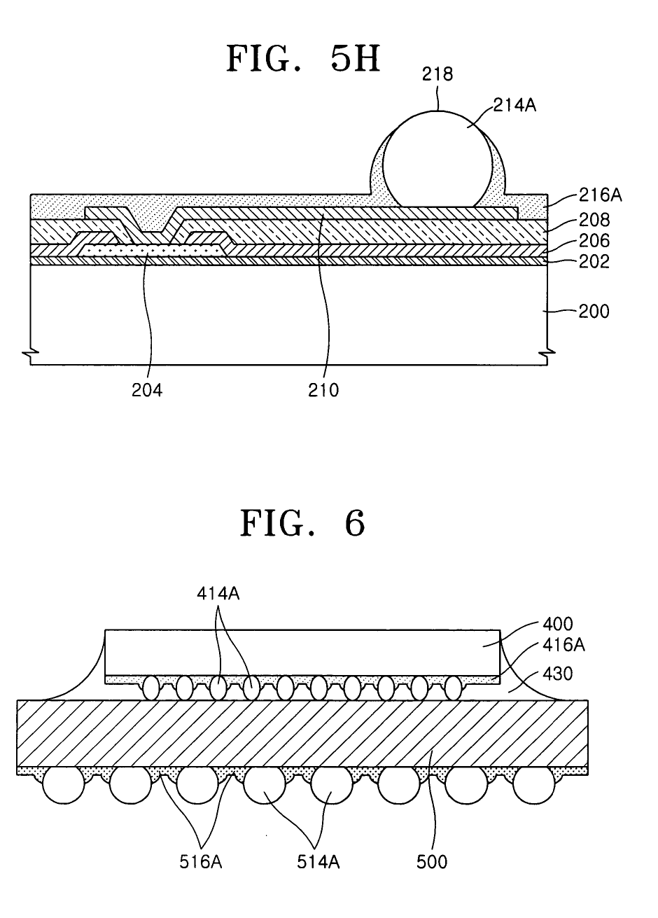

FIGS. 5A through 5H are schematic cross-sectional views for explaining a method of manufacturing a semiconductor package according to an embodiment of the present invention.

Referring initially to FIG. 5A, a semiconductor structure is fabricated or provided so as to generally include a semiconductor substrate 200, an integrated circuit layer 202, a chip pad 204, a passivation layer 206, and an insulating layer 208. The insulating layer may, for example, be formed of BCB (Benzo Cyclo Butene), polyimide, epoxy, silicon oxide, silicon nitrite, or composites of these materials. Also, as shown, an opening is formed through the passivation layer 206 and the insulating layer 208 to expose a top surface region of the chip pad 204. In this example, the insulating layer 208 extends to the surface of the chip pad 204, and accordingly, the sidewalls of the opening are defined by the insulating layer 208.

Referring to FIG. 5B, a conductive redistribution pattern 210 is formed on the insulating layer 208 so as to electrically contact the chip pad 204 via the opening in the insulating layer 208 and the passivation layer 206.

Then, referring to FIG. 5C, a sacrificial photoresistive layer 213 is patterned over the conductive redistribution pattern 210 with an opening therein that exposes a top surface portion of the redistribution pattern 210. In this embodiment, the sacrificial photoresistive layer 213 is used for positioning of a solder ball during a later reflow process, and the exposed surface portion of the redistribution pattern 210 defines a solder ball pad 215.

Next, referring to FIGS. 5D and 5E, a solder ball 214 is positioned on the solder ball pad 215, and then subjected to a thermal reflow process to adhere the resultant reflowed solder ball 214A to the underlying solder ball pad 215.

Then, referring to FIG. 5F, the sacrificial photoresistive layer 213 is removed to expose the underlying redistribution pattern 210.

Referring to FIG. 5G, a photosensitive polymer layer 216 is coated over the structure of FIG. 5F so as to cover the reflowed solder ball 214A and the redistribution pattern 210. The photosensitive polymer layer 216 may, for example, be formed of polyimide or PBO (PolyBenzOxazol), and may, for example, be deposited by screen printing, spin coating, or dispensing techniques, or by dipping the structure of FIG. 5F into a liquid of the polymer material.

Next, referring to FIG. 5H, the photosensitive polymer layer 216 of FIG. 5G is subjected to a photolithography process in which a portion of the polymer layer is removed to define a reinforcing polymer layer 216A having an opening which exposes a top portion of the solder ball 214A. Like the embodiment of FIG. 4G, a portion of reinforcing polymer layer 216A surrounds a sidewall portion of the solder ball 214A. Preferably, the diameter of the solder ball 214A is greater than a diameter in the opening in the reinforcing polymer layer 216A.

The photolithography process includes well-known exposure and development processes to remove selected portions of the photosensitive polymer layer 216. In addition, after development, the process preferably includes heat treatment at a temperature which exceeds the viscosity temperature of the polymer material of the layer 216. Such heat treatment is effective in achieving curing and reflowing of the photosensitive polymer layer 216. As illustrated in FIG. 5H, the reflow of the polymer material results in the tapering of the portion of the reinforcing polymer layer 216A contacting the side of the solder ball 214A. For example, in the case of polyimide, the heat treatment may be conducted at 300° C. to 350° C. Also for example, in the case of PBO, the heat treatment may be conducted at 280° C. to 350° C.

Although not shown, the IC chip structure of FIG. 5H typically will include a plurality of solder balls 214A. Also, while the invention is not limited to wafer level processing, the IC chip structure of FIG. 5H may constitute one of a plurality of simultaneously formed chip structures on a single semiconductor wafer. In this case, scribe lines between adjacent pairs of IC chips on the wafer are preferably exposed during the same photolithography process used to expose the solder ball 214A through the reinforcing layer 216A. The wafer may then be subjected to a sawing process in which it is separated into a plurality of IC chips along the scribe lines. Removal of the photoresistive polymer layer over the scribe lines is effective in avoiding the dicing saw from becoming contaminated with polymer residues.

The reinforcing polymer layer 216A of FIG. 5H is effective in absorbing various stresses applied to solder ball, particularly when the IC chip is mounted to a circuit board and used for an extended period of time. Additionally, in contrast to the fabrication technique described previously in connection with FIG. 3, the use of a photoresistive polymer layer and photolithography to expose the solder ball 214A through the reinforcing layer 216A allows for more precise structural definition of the exposed portion of the solder ball 214A. As such, better uniformity of the exposed portions across the plural solder balls of each IC chip can be realized, which in turn allows for improved adhesion and electrical contact with the printed circuit board of any later formed IC package.

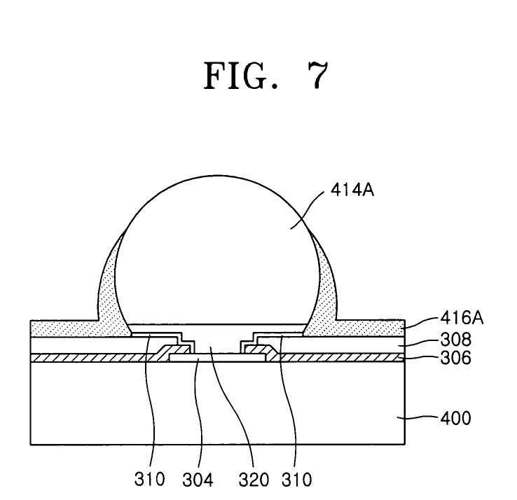

FIG. 6 is a schematic cross-sectional view of a flip chip package according to an embodiment of the present invention, and FIG. 7 is a schematic cross-sectional view of a solder bump structure of the flip chip package of FIG. 6 according to an embodiment of the present invention.

Referring collectively to FIGS. 6 and 7, the flip chip package includes an IC chip 400 having an array of solder bumps 414A electrically mounted to respective chip pads 304 through an insulating layer 308 and passivation layer 306. Interposed between the solder bump 414A and chip pad 304 are an adhesion layer 310 and a stud layer 320. The stud layer 320 may, for example, be formed of nickel or a nickel alloy.

A reinforcing layer 416A covers the surface of the IC chip 400 while exposing top portions of the solder bumps 414A. The reinforcing layer 416A is formed of a polymer which is photo-sensitive in its procured state, and may be formed according the embodiments described above in connection with FIGS. 4A through 4G, and FIGS. 5A through 5H.

Reference number 430 of FIG. 7 denotes a protective resin. As shown, the array of solder bumps 414A respectively contact electrode pads (not shown) on one side of a PCB substrate 500. The other side of the PCB substrate 500 is equipped with an array of solder balls 514A. A reinforcing layer 616A covers this side of the PCB substrate 500 while exposing top portions of the solder balls 514A. The reinforcing layer 516A is formed of a polymer which is photo-sensitive in its procured state, and may be formed according the embodiments described above in connection with FIGS. 4A through 4G, and FIGS. 5A through 5H.

The embodiment of FIG. 7 differs from prior embodiments in that no distribution pattern is utilized and in that the electrode is a bump electrode, rather than a ball electrode. In this regard, it is noted that the present invention is not limited to bump electrodes and ball electrodes, which are generally considered terms of art. That is, bump electrodes are characterized by being relative small and fabricated directly on the IC chip (or PCB) using screen printing processes and the like. Ball electrodes, on the other hand, are characterized by being relatively large and pre-fabricated.

Also, the present invention is not limited to electrodes made of a solder material.

Finally, although the present invention has been described above in connection with the preferred embodiments thereof, the present invention is not so limited. Rather, various changes to and modifications of the preferred embodiments will become readily apparent to those of ordinary skill in the art. Accordingly, the present invention is not limited to the preferred embodiments described above. Rather, the true spirit and scope of the invention is defined by the accompanying claims.

What is claimed is:

1. A method of manufacturing a semiconductor device, comprising:
depositing a photosensitive layer to cover an exposed portion of an electrode with the photosensitive layer; and
subjecting the photosensitive layer to a photolithography process to partially remove the photosensitive layer covering the electrode.

2. The method as claimed in claim 1, wherein the electrode is one of a ball electrode and a bump electrode.

3. The method as claimed in claim 2, wherein a bottom of the electrode is mounted to a conductive layer, and wherein the partial removal of the photosensitive layer exposes a top portion of the electrode.

4. The method as claimed in claim 3, wherein a diameter of the electrode is greater than a diameter of the exposed top portion of the electrode.

5. The method as claimed in claim 3, wherein the conductive layer is located on a semiconductor chip.

6. The method as claimed in claim 3, wherein the conductive layer is located on a printed circuit board.

7. The method as claimed in claim 1, wherein the photolithography process includes exposure of the photosensitive layer, development of the exposed photosensitive layer, and heat treatment of the developed photosensitive layer.

8. The method as claimed in claim 7, wherein a temperature of the heat treatment exceeds a viscosity temperature of the photosensitive layer.

9. The method as claimed in claim 8, wherein the photosensitive layer includes polyimide, and the temperature of the heat treatment is in the range of 300° to 350° C.

10. The method as claimed in claim 8, wherein the photosensitive layer includes PolyBenzOxazol, and the temperature of the heat treatment is in the range of 280° to 350° C.

11. The method as claimed in claim 1, wherein the photosensitive layer is further deposited onto an insulating layer located adjacent the electrode.

12. The method as claimed in claim 3, wherein the photosensitive layer is further deposited onto the conductive layer.

13. The method as claimed in claim 1, wherein the photosensitive layer comprises a least one of polyimide and PolyBenzOxazol.

14. A method of manufacturing a semiconductor device, comprising:
providing a semiconductor element which includes a surface and a plurality of electrodes having respective bottom portions mounted to the surface;
depositing a photosensitive layer to cover the surface and the electrodes of the semiconductor element; and
subjecting the photosensitive layer to a photolithography process to partially remove the photosensitive layer so as to expose respective top portions of the electrodes.

15. The method of claim 14, wherein, after the photolithography process, the photosensitive layer includes a plurality of openings aligned over the top portions of the electrodes, respectively, and wherein a diameter of each of the openings is less than a diameter of each of the electrodes.

16. The method of claim 15, wherein, after the photolithography process, the photosensitive layer includes a generally flat top surface and a plurality of tapered portions extending along and protecting a side of the plurality of electrodes, respectively.

17. The method as claimed in claim 14, wherein the photolithography process includes exposure of the photosensitive layer, development of the exposed photosensitive layer, and heat treatment of the developed photosensitive layer.

18. The method as claimed in claim 17, wherein a temperature of the heat treatment exceeds a viscosity temperature of the photosensitive layer.

19. The method as claimed in claim 14, wherein the photosensitive layer includes at least one of polyimide and PolyBenzOxazol.

20. The method as claimed in claim 14, wherein each of the plurality of electrodes is one of a ball electrode and a bump electrode.

21. A method of manufacturing a wafer level package, comprising:
providing a wafer having a surface which includes a plurality of chip regions separated by scribe lines, and a plurality of electrodes having respective bottom surfaces mounted in each of the chip regions;
covering the surface of the wafer with a photosensitive layer;
subjecting the photosensitive layer to a photolithography process to partially remove the photosensitive layer so as to expose respective top portions of the electrodes in each of the chip regions.

22. The method as claimed in claim 21, wherein the photolithography process further at least partially removes portions of the photosensitive layer covering the scribe lines separating the chip regions.

23. The method as claimed in claim 22, further comprising dicing the wafer along the scribe lines.

24. The method as claimed in claim 21, wherein the photolithography process includes exposure of the photosensitive layer, development of the exposed photosensitive layer, and heat treatment of the developed photosensitive layer.

25. The method as claimed in claim 24, wherein a temperature of the heat treatment exceeds a viscosity temperature of the photosensitive layer.

26. The method as claimed in claim 21, wherein the photosensitive layer includes at least one of polyimide and PolyBenzOxazol.

27. The method as claimed in claim 21, wherein each of the plurality of electrodes is one of a ball electrode and a bump electrode.

28. A semiconductor device comprising an electrode which includes a bottom portion mounted to a conductive layer and which is partially embedded in a polymer layer, wherein a top portion of the electrode is exposed through an opening in the polymer layer, and wherein the polymer layer is formed of a material that is photosensitive when in a pre-cured state.

29. The semiconductor device as claimed in claim 28, wherein the electrode is one of a ball electrode and a bump electrode.

30. The semiconductor device as claimed in claim 29, wherein a diameter the electrode is greater than a diameter of the exposed top portion of the electrode.

31. The semiconductor device as claimed in claim 28, wherein the polymer layer includes at least one of polyimide and PolyBenzOxazol.

32. A semiconductor device comprising:
a semiconductor element which includes a surface and a plurality of electrodes having respective bottom portions mounted to the surface; and
a polymer layer which covers the surface of the semiconductor element and which includes a plurality of openings which respectively partially expose a top portion of the electrodes, wherein the polymer layer is formed of a material that is photosensitive when in a pre-cured state.

33. The semiconductor device as claimed in claim 32, wherein each of the plurality of electrodes is one of a ball electrode and a bump electrode.

34. The semiconductor device as claimed in claim 33, wherein a diameter of each of the electrodes is greater than a diameter of each exposed top portion of the electrodes.

35. The semiconductor device as claimed in claim 32, wherein the semiconductor element is a semiconductor chip of a wafer level package.

36. The semiconductor device as claimed in claim 32, wherein the semiconductor element is a semiconductor chip of a flip-chip package, and wherein the top portions of the electrodes contact a first surface of printed circuit board of the flip-chip package.

37. The semiconductor device as claimed in claim 32, wherein the polymer layer includes at least one of polyimide and PolyBenzOxazol.

38. The semiconductor device as claimed in claim 32, wherein an opposite second surface of the printed circuit board includes a plurality of second electrodes, and wherein a second polymer layer covers the second surface of the printed circuit board and includes a plurality of openings which respectively partially expose a top portion of the second electrodes.

39. The semiconductor device as claimed in claim 38, wherein the second polymer layer is formed of a material that is photosensitive when in a pre-cured state.

40. A semiconductor device comprising:
a semiconductor element which includes a conductive layer and a plurality of electrodes having respective bottom portions mounted to the conductive layer; and
a polymer layer which contacts the conductive layer of the semiconductor element and which includes a plurality of openings which respectively partially expose a top portion of the electrodes;
wherein a diameter of each of the electrodes is greater than a diameter of each of the exposed top portions of the electrodes.

41. The semiconductor device as claimed in claim 40, wherein the conductive layer is a redistribution layer of a wafer level package.

42. The semiconductor device as claimed in claim 40, wherein the polymer layer is formed of a material that is photosensitive when in a pre-cured state.

43. The semiconductor device as claimed in claim 40, wherein each of the plurality of electrodes is one of a ball electrode and a bump electrode.

44. The semiconductor device as claimed in claim 43, wherein a diameter of each of the electrodes is greater than a diameter of each exposed top portion of the electrodes.

45. The semiconductor device as claimed in claim 43, wherein the polymer layer includes at least one of polyimide and PolyBenzOxazol.
